(19) United States
(12) Patent Application Publication
(10) Pub. No.: US 2026/0064168 A1
(43) Pub. Date: Mar. 5, 2026

(54) ELECTRONIC DEVICE

(71) Applicants: SQ TECHNOLOGY (SHANGHAI) CORPORATION, Shanghai (CN); INVENTEC CORPORATION, Taipei (TW)

(72) Inventors: Fanpu He, Shanghai (CN); Shuai Zhang, Shanghai (CN); Guangzhao Tian, Shanghai (CN); Hong-Chou Lin, Taipei (TW); Yu-Fan Chen, Taipei (TW)

(21) Appl. No.: 18/988,846

(22) Filed: Dec. 19, 2024

(30) Foreign Application Priority Data
Aug. 29, 2024 (CN) 202411207254.0

(51) Int. Cl. G06F 1/18

(52) U.S. Cl. CPC G06F 1/183; G06F 1/189

(57) ABSTRACT

An electronic device includes: a computer case; a cross-beam assembly including a cross-beam body, two ends of the cross-beam body along a first direction being connected to two opposite side walls of the computer case, respectively, the cross-beam body and the computer case enclosing a accommodating cavity, the cross-beam body comprising a first connecting portion and a first plug-in portion that are staggered in the first direction; and a GPU assembly provided including a GPU video card and a first bracket. The GPU video card has a first end, the first end comprising a second plug-in portion, the first bracket is provided at the first end and comprising a second connecting portion, the second plug-in portion and the second connecting portion are staggered in the first direction, the first plug-in portion is plugged into the second plug-in portion, and the first connecting portion is connected to the second connecting portion.

### CROSS-REFERENCE TO RELATED APPLICATIONS

This application claims priority of Chinese Patent Application No. 2024112072540, filed on Aug. 29, 2024, entitled “ELECTRONIC DEVICE”, the entire content of which is incorporated herein by reference in its entirety.

### TECHNICAL FIELD

The present disclosure relates to the technical field of electronic products, and in particular to an electronic device.

### BACKGROUND

As a power of the GPU video card increases, a weight of the GPU video card also increases, which causes a PCIE slot to bear too much weight, resulting in damage to the PCIE slot. In order to avoid damage to the PCIE slot, a cross-beam assembly is usually fixed in a computer case, and a bracket is used to fix the GPU video card on the cross-beam assembly.

If GPU video cards of different lengths need to be mounted, the cross-beam assembly is moved, so that a accommodating cavity formed by the cross-beam assembly and the computer case is adapted to the length of the GPU video card, which will reduce the mounting efficiency.

### SUMMARY

Accordingly, it is necessary to provide an electronic device capable of mounting GPU assemblies of different lengths while improving the mounting efficiency.

An electronic device includes:
a computer case;
a cross-beam assembly provided in the computer case, wherein the cross-beam assembly includes a cross-beam body, two ends of the cross-beam body along a first direction are connected to two opposite side walls of the computer case, respectively, the cross-beam body and the computer case cooperatively enclose an accommodating cavity, the cross-beam body includes a first connecting portion and a first plug-in portion that are staggered in the first direction; and
a GPU assembly provided in the accommodating cavity, wherein the GPU assembly includes a GPU video card and a first bracket, the GPU video card has a first end facing the cross-beam assembly, the first end includes a second plug-in portion, the first bracket is provided at the first end and includes a second connecting portion, the second plug-in portion and the second connecting portion are staggered in the first direction, the first plug-in portion is plugged into the second plug-in portion, and the first connecting portion is connected to the second connecting portion.

In one of the embodiments, the first bracket further includes a first mounting portion and a second mounting portion, the first mounting portion is spaced apart from the second plug-in portion along a second direction, the second direction is perpendicular to the first direction, the second mounting portion is provided on a side of the first mounting portion, the second mounting portion extends from the first mounting portion toward the cross-beam assembly, the second connecting portion is provided on a side of the second mounting portion away from the first mounting portion, so that the first mounting portion and the second connecting portion are staggered in the first direction.

In one of the embodiments, the second connecting portion extends from the second mounting portion toward the cross-beam assembly, so that the second connecting portion is connected to the first connecting portion.

In one of the embodiments, the cross-beam body further includes a first guiding portion facing the first end, the first guiding portion is in guiding cooperation with a side of the second mounting portion away from the first mounting portion, and the first guiding portion is configured to guide a movement of the first bracket along the second direction.

In one of the embodiments, the first guiding portion is provided with a guiding slot extending along the second direction, a notch of the guiding slot faces the first end, a top wall of the first guiding portion along the second direction is provided with a first insertion opening in communication with the guiding slot, and the side of the second mounting portion away from the first mounting portion is provided in the guiding slot through the first insertion opening.

In one of the embodiments, the first connecting portion and the first plug-in portion are provided on a top portion of the cross-beam body along a second direction, the top portion of the cross-beam body is lower than a bottom portion of the second plug-in portion in the second direction, and the first direction is perpendicular to the second direction.

In one of the embodiments, the cross-beam body is provided with a first ventilation hole in communication with the accommodating cavity.

In one of the embodiments, the computer case includes a housing and a cover, a top portion of the housing in a second direction is provided with a first opening, the cover is provided in the first opening, the cover is capable of moving on the housing along a third direction, the cover is provided with a latch assembly, the latch assembly is provided with a locking hole, the first direction, the second direction, the third direction are perpendicular to each other, the cross-beam assembly further comprises a guiding member, the guiding member is provided on the cross-beam body along the second direction, and an end of the guiding member away from the cross-beam body is provided in the locking hole.

In one of the embodiments, the cross-beam body is provided with a first protrusion provided on a side thereof away from the GPU assembly, the first protrusion extends in a direction away from the GPU assembly, and the guiding member is connected to the first protrusion.

In one of the embodiments, the cross-beam assembly further includes a first support frame, the first support frame is provided on a side of the first protrusion facing the cover, the first support frame is connected to the guiding member, and the first support frame is configured to support the guiding member.

In one of the embodiments, a bottom portion of the cross-beam body along the second direction is provided with a second protrusion, and the second protrusion is opposite to the first protrusion, the cross-beam assembly further includes a second support frame provided between the first protrusion and the second protrusion, and the second support frame is configured to support the first protrusion.

In one of the embodiments, two opposite side walls of the computer case are each provided with a second guiding portion, the second guiding portion is in guiding cooperation with an end of the cross-beam body along the first direction, and the second guiding portion is configured to guide a movement of the cross-beam body along a second direction.

In one of the embodiments, both ends of the cross-beam body along the first direction are each provided with a limiting groove, the limiting groove extends along a second direction, a bottom wall of the limiting groove along the second direction is provided with a second insertion opening in communication with the limiting groove, two opposite side walls of the computer case are each provided with a limiting member, and the limiting member is provided in the limiting groove through the second insertion opening.

In one of the embodiments, the first plug-in portion is provided with a first power connector, the second plug-in portion is provided with a second power connector, and the first power connector is electrically connected to the second power connector.

In one of the embodiments, a plurality of first plug-in portions and a plurality of first connecting portions are provided, the plurality of first plug-in portions and the plurality of first connecting portions are alternately arranged along the first direction, a plurality of GPU assemblies are provided, the plurality of GPU assemblies are arranged along the first direction, a plurality of second plug-in portions and a plurality of second connecting portions are alternately arranged along the first direction, the plurality of first plug-in portions are plugged into the plurality of second plug-in portions in a one-to-one correspondence, and the plurality of first connecting portions are connected to the plurality of second connecting portions in a one-to-one correspondence.

In one of the embodiments, the electronic device further includes a tray and a GPU card that are accommodated in the accommodating cavity, tray is located below the GPU video card along a second direction, the GPU card is connected to a side of the tray facing the GPU video card, and the GPU card is electrically connected to the GPU video card.

In one of the embodiments, the tray is provided with a first area, the first area is provided with a first group of holes and a second group of holes, the first group of holes are configured to mount a switch card, and the second group of holes are configured to mount a HBA (Host Bus Adapter) card.

In one of the embodiments, the first area is provided with a plurality of common holes, a plurality of first mounting holes, and a plurality of second mounting holes, the plurality of common holes and the plurality of first mounting holes form the first group of holes, the first group of holes are configured to be in communication with hole positions of the switch card in a one-to-one correspondence, the plurality of common holes and the plurality of second mounting holes form the second group of holes, and the second group of holes are configured to be in communication with hole positions of the HBA card in a one-to-one correspondence.

In one of the embodiments, the tray is provided with a first gourd hole, the first gourd hole includes a first hole and a second hole, a diameter of the first hole is less than a diameter of the second hole, the first hole and the second hole are arranged along a third direction, the first hole is in communication with the second hole, the computer case has a bottom wall, the bottom wall is provided with a fixing member provided in the first gourd hole, the fixing member is capable of moving in the first gourd hole along the third direction, so that the tray has a locked state and an unlocked state, the fixing member is provided in the first hole when the tray is in the locked state, and the fixing member is provided in the second hole when the tray is in the unlocked state.

In one of the embodiments, an edge of the tray and the first area enclose a second area, the second area is provided with a first fastening hole and a positioning hole, the positioning hole extends along a third direction, a bottom wall of the computer case is further provided with a second fastening hole and a via hole, a first fastening member is provided in the first fastening hole and the second fastening hole, and a positioning member is provided in the positioning hole and the via hole.

When mounting the electronic device, the GPU video card is first placed in the accommodating cavity, and the second plug-in portion of the GPU video card is plugged into the first plug-in portion of the cross-beam body. Then, the second connecting portion of the first bracket is connected to the first connecting portion of the cross-beam body. In this way, the GPU assembly is fixed to the cross-beam module, and the cross-beam assembly supports the GPU assembly, so as to avoid performance damage of the GPU assembly due to excessive weight of the GPU assembly. If the GPU video card is long, after the GPU video card is placed in the accommodating cavity, a distance between the first end of the GPU video card and the cross-beam assembly is small, which will affect the second plug-in portion plugged into the first plug-in portion and affect the second plug-in portion plugged out from the first plug-in portion. Therefore, in the present disclosure, along the first direction, the first plug-in portion and the first connecting portion are staggered, the second plug-in portion and the second connecting portion are staggered, the first plug-in portion is plugged into the second plug-in portion, and the first connecting portion is connected to the second connecting portion, so that the plug-in operation of the first plug-in portion and the second plug-in portion will not interfered, and the connection operation of the first connecting portion and the second connecting portion will not be interfered. In this way, when the mounting position of the cross-beam assembly remains unchanged, that is, a size of the accommodating cavity remains unchanged, the cross-beam assembly can be compatible with the mounting of GPU video cards of different lengths, a time spent on adjusting the mounting position of the cross-beam assembly in the case is reduced, and the mounting efficiency is improved.

The details of one or more embodiments of the application are set forth in the accompanying drawings and the description below. Other features, objects, and advantages of the application will be apparent from the description and drawings, and from the claims.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 is a perspective view of an electronic device according to an embodiment.

FIG. 2 is a perspective view of the electronic device of FIG. 1, with a cover removed.

FIG. 3 is a perspective view showing of a cross-beam assembly mounted in a housing according to an embodiment.

FIG. 4 is an enlarged view of a portion A in FIG. 3.

FIG. 5 is a perspective view showing a tray and a GPU card that are mounted in the housing according to an embodiment.

FIG. 6 is an enlarged view of a portion B in FIG. 5.

FIG. 7 is an enlarged view of a portion C in FIG. 5.

FIG. 8 is a perspective view of the cross-beam assembly according to an embodiment.

FIG. 9 is similar to FIG. 8, but viewed from another aspect.

FIG. 10 is a left side view of the cross-beam assembly of FIG. 8.

FIG. 11 is a perspective view of a GPU assembly according to an embodiment.

FIG. 12 is similar to FIG. 11, but viewed from another aspect.

FIG. 13 is a perspective view of a first bracket according to an embodiment.

FIG. 14 is a perspective view of the tray according to an embodiment.

FIG. 15 is a perspective view of a rear window according to an embodiment.

FIG. 16 is a perspective view of a pressing member shown in FIG. 15.

FIG. 17 is a perspective view of the rear window according to another embodiment.

FIG. 18 is a perspective view of the pressing member shown in FIG. 17.

FIG. 19 is a perspective view of a mounting base shown in FIG. 17.

### DESCRIPTION OF REFERENCE NUMERALS

10. Computer case; 11. Housing; 111. First opening; 112. Second opening; 113. Second guiding portion; 1131. First guiding body; 1132. Second guiding body; 114. Limiting member; 115. Fourth connecting hole; 116. Second connecting member; 117. Bottom wall; 1171. Second fastening hole; 1173. Positioning member; 1174. First fastening member; 1176. Second fastening member; 12. Cover; 13. Rear window; 131. Flange; 1311. Third fastening member; 1312. Fourth fastening hole; 1313. Second positioning portion; 1314. Support portion; 132. Second fastening member; 14. Accommodating cavity; 15. Latch assembly; 16. Mounting base; 161. Second through hole; 162. First positioning portion; 17. Connecting shaft; 18. Elastic member; 20. Cross-beam assembly; 21. Cross-beam body; 211. First connecting portion; 2111. First connecting hole; 212. First plug-in portion; 213. First guiding portion; 2131. Guiding groove; 2132. First insertion opening; 214. First protrusion; 215. Second protrusion; 216. Limiting groove; 2161. Second insertion opening; 217. Connecting lug; 2171. Third connecting hole; 218. First ventilation hole; 22. First connecting member; 23. Guiding member; 24. First support frame; 241. First through hole; 25. Second support frame; 251. Second ventilation hole; 30. GPU assembly; 31. GPU video card; 311. First end; 3111. Second plug-in portion; 3112. Fixing hole; 31121. First fixing hole; 31122. Second fixing hole; 312. Second end; 32. First bracket; 321. Second connecting portion; 3211. Second connecting hole; 322. First mounting portion; 3221. Through hole; 32211. First through hole; 32212. Second through hole; 32213. Third through hole; 32214. Fourth through hole; 323. Second mounting portion; 34. First fixing member; 35. Second bracket; 351. Third connecting portion; 3511. Fifth connection hole; 40. Tray; 41. First area; 411. First group of holes; 4111. Common hole; 4112. First mounting hole; 412. Second group of holes; 4121. Second mounting hole; 413. First gourd hole; 4131. First hole; 4132. Second hole; 42. Second area; 421. Second positioning hole; 422. First fastening hole; 50. GPU card; 60. Pressing member; 61. Second gourd hole; 611. Third hole; 612. Fourth hole; 62. Third fastening hole; 63. First side; 64. Second side.

### DETAILED DESCRIPTION OF THE EMBODIMENTS

In order to make the above objectives, features and advantages of the present disclosure clear and easier to understand, the specific embodiments of the present disclosure are described in detail below in combination with the accompanying drawings. Many specific details are set forth in the following description to facilitate a full understanding of the present disclosure. However, the present disclosure can be implemented in many ways different from those described herein, and those skilled in the art can make similar improvements without departing from the connotation of the present disclosure. Therefore, the present disclosure is not limited by the specific embodiments disclosed below.

In the description of the present disclosure, it should be understood that the terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential direction” are based on the azimuths or position relationships shown in the attached drawings. These terms are only for the convenience of describing the present disclosure and simplifying the description, rather than indicating or implying that the indicated devices or elements must have the specific azimuths, or be constructed or operated in the specific azimuths, and therefore such terms cannot be understood as limitations of the present disclosure.

In addition, the terms “first” and “second” are only used for descriptive purposes and cannot be understood as indicating or implying relative importance or implicitly indicating the number of indicated technical features. Thus, the features defined with “first” and “second” may explicitly or implicitly include at least one of the features. In the description of the present disclosure, “a plurality of” means at least two, such as two, three, etc., unless otherwise expressly and specifically defined.

In the present disclosure, unless otherwise expressly specified and limited, the terms “mount”, “connect”, “couple”, “fix” and the like should be interpreted broadly. For example, the terms can mean fixed connection, detachable connection, or being integrated. The terms can mean mechanical connection or electrical connection. The terms can mean directly connection or indirectly connection through an intermediate medium. The terms can mean connection within two elements or interaction relationship between two elements, unless otherwise expressly limited. For those skilled in the art, the specific meaning of the above terms in the present disclosure should be understood according to the specific situation.

In the present disclosure, unless otherwise expressly specified and limited, a first feature “above” or “below” a second feature may be in direct contact with the second feature, or the first and second features may be in indirect contact through an intermediate medium. Moreover, the first feature “above” the second feature may be right above or obliquely above the second feature, or the first feature may be merely located at a height higher than the second feature. The first feature “below” the second feature may be right below or obliquely below the second feature, or the first feature may be merely located at a height lower than that of the second feature.

It should be noted that when an element is called “fixed to” or “mounted on” another element, it can be directly on another element or there can be an intermediate element. When an element is considered to be “connected” to another element, it can be directly connected to another element or there can be an intermediate element. The terms “vertical”, “horizontal”, “up”, “down”, “left”, “right” and similar expressions used herein are for the purpose of illustration only and do not represent the only ways for implementation.

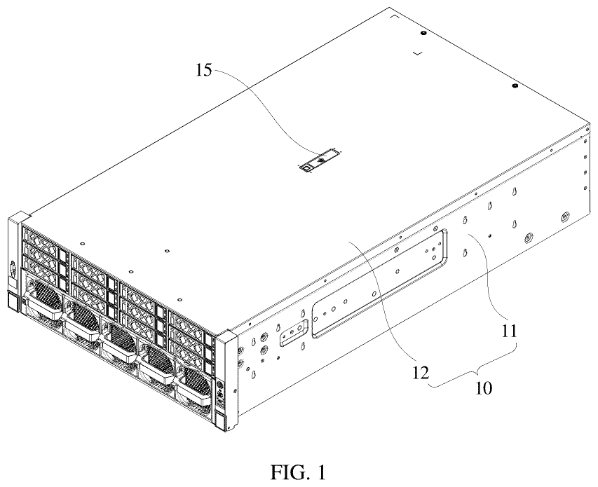

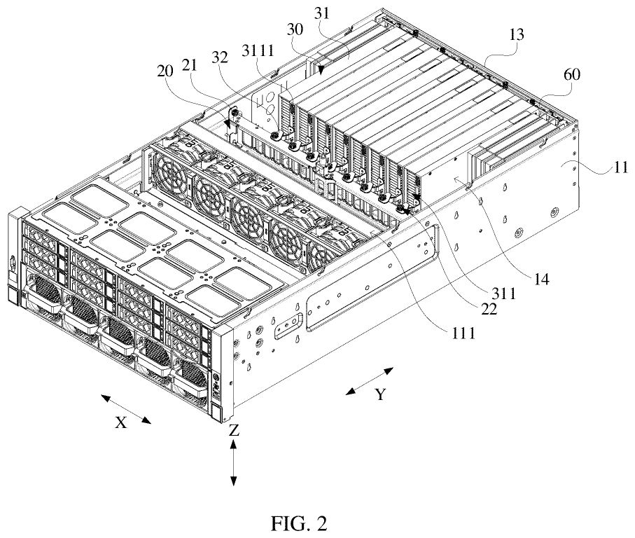

Referring to FIG. 1 and FIG. 2, in an embodiment, an electronic device is provided, which includes a computer case 10, a cross-beam assembly 20, and a graphics processing unit (GPU) assembly 30. The cross-beam assembly 20 and the GPU assembly 30 are provided in the computer case 10. In an embodiment, the electronic device is a server. In another embodiment, the electronic device may be other types of electronic products, such as personal computer, which is not limited thereto.

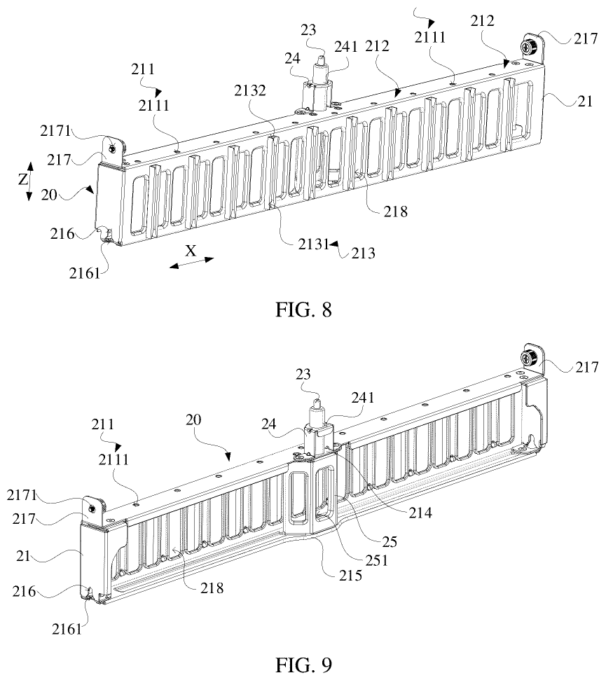

In an embodiment, referring to FIG. 2, the cross-beam assembly 20 includes a cross-beam body 21. Two ends of the cross-beam body 21 along a first direction X are connected to two opposite side walls of the computer case 10, respectively. The cross-beam body 21 and the computer case 10 enclose an accommodating cavity 14, and the GPU assembly 30 is provided in the accommodating cavity 14. Referring to FIG. 8, the cross-beam body 21 includes a first connecting portion 211 and a first plug-in portion 212 that are staggered in the first direction X.

It should be noted that a thickness of the cross-beam body 21 can be configured according to actual requirements. In an embodiment, the thickness of the cross-beam body 21 is 1.2 mm.

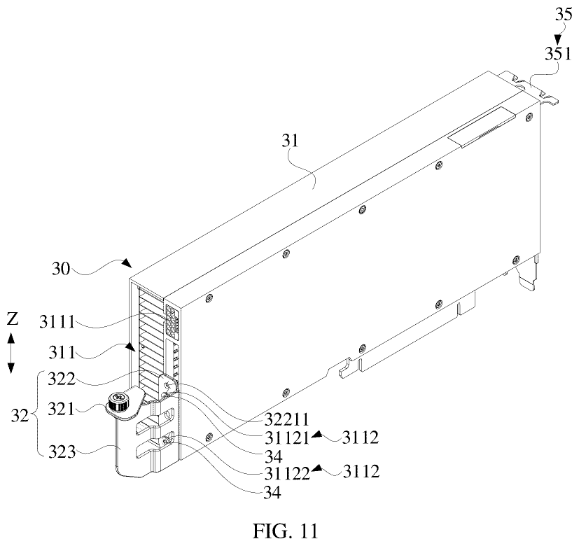

In an embodiment, referring to FIG. 2 and FIG. 11, the GPU assembly 30 includes a GPU video card 31 and a first bracket 32. The GPU video card 31 has a first end 311 facing the cross-beam assembly 20, and the first end 311 includes a second plug-in portion 3111. The first bracket 32 is connected to the first end 311 and includes a second connecting portion 321. The second connecting portion 321 and the second plug-in portion 3111 are staggered in the first direction X. The first connecting portion 211 is plugged into the second connecting portion 321, and the first plug-in portion 212 is connected to the second plug-in portion 3111.

In an embodiment, the first plug-in portion 212 is provided with a first power connector, the second plug-in portion 3111 is provided with a second power connector, and the first power connector is electrically connected to the second power connector. In other embodiments, the first plug-in portion 212 and the second plug-in portion 3111 may also be provided with other plug-in devices, which is not limited thereto.

In an embodiment, referring to FIG. 8, the first connecting portion 211 and the first plug-in portion 212 are provided on a top portion of the cross-beam body 21 in a second direction Z perpendicular to the second direction X.

Further, in the second direction Z, the top portion of the cross-beam body 21 is lower than a bottom portion of the second plug-in portion 3111. It should be noted that a height of the cross-beam body 21 is determined according to the actual assembly of the GPU video card 31, and it is sufficient to ensure that the top portion of the cross-beam body 21 is lower than the bottom portion of the second plug-in portion 3111. In this way, in a height direction, the cross-beam body 21 can avoid the second plug-in portion 3111, that is, the cross-beam body 21 can avoid a plug-in area, so as to reserve sufficient space for a plug-in and pull-out operations of the first plug-in portion 212 and the second plug-in portion 3111.

In an embodiment, referring to FIG. 11 and FIG. 13, the first bracket 32 further includes a first mounting portion 322 and a second mounting portion 323. The first mounting portion 322 is spaced apart from the second plug-in portion 3111 along the second direction Z. Optionally, the first mounting portion 322 is located below the second plug-in portion 3111 in the second direction Z. The second mounting portion 323 is provided on a side of the first mounting portion 322, and the second mounting portion 323 extends from the first mounting portion 322 toward the cross-beam body 21. The second connecting portion 321 is provided on a side of the second mounting portion 323 away from the first mounting portion 322, so that the first mounting portion 322 and the second connecting portion 321 are staggered in the first direction X. During mounting, the first bracket 32 is mounted to the first end 311 of the GPU video card 31 through the first mounting portion 322. After the first bracket 32 is mounted to the GPU video card 31, the first mounting portion 322 and the second plug-in portion 3111 are spaced apart along the second direction Z. Since the second connecting portion 321 is provided on the side of the second mounting portion 323 away from the first mounting portion 322, the second connecting portion 321 and the first mounting portion 322 are staggered in the first direction X to avoid mounting interference.

Further, referring to FIG. 2, FIG. 11 and FIG. 13, the second connecting portion 321 extends from the second mounting portion 323 toward the cross-beam body 21, so that the second connecting portion 321 is overlapped with the first connecting portion 211. During mounting, the second connecting portion 321 is overlapped on the first connecting portion 211, so that the first connecting portion 211 and the second connecting portion 321 are conveniently connected.

In an embodiment, referring to FIG. 2 and FIG. 11, the first connecting portion 211 and the second connecting portion 321 are detachably connected. In this way, the first bracket 32 can be removed from the cross-beam body 21 to facilitate replacement and maintenance of the first bracket 32 and the GPU assembly 30.

Optionally, referring to FIG. 2, FIG. 8 and FIG. 13, the first connecting portion 211 is provided with a first connecting hole 2111, the second connecting portion 321 is provided with a second connecting hole 3211, and a first connecting member 22 is provided in the first connecting hole 2111 and the second connecting hole 3211. The first connecting member 22 may be a bolt, etc. During mounting, the second connecting portion 321 is overlapped on the first connecting portion 211, so that the first connecting hole 2111 is in communication with the second connecting hole 3211, and then the first connecting member 22 is provided in the first connecting hole 2111 and the second connecting hole 3211. In this way, the first bracket 32 can be detachably attached to the cross-beam body 21. In other embodiments, the first connecting portion 211 may be engaged with the second connecting portion 321.

In an embodiment, referring to FIG. 2, a plurality of GPU assemblies 30 are provided, and the plurality of GPU assemblies 30 are arranged in the accommodating cavity 14 side by side along the first direction X. In this way, the performance of the electronic device can be improved.

In an embodiment, referring to FIG. 2, FIG. 8 and FIG. 11, the cross-beam body 21 further includes a first guiding portion 213. The first guiding portion 213 is provided toward the first end 311 of the GPU video card 31, and the first guiding portion 213 is in guiding cooperation with the side of the second mounting portion 323 away from the first mounting portion 322. During the process of placing the GPU assembly 30 into the accommodating cavity 14, the side of the second mounting portion 323 away from the first mounting portion 322 is in guiding cooperation with the first guiding portion 213. Under the action of the first guiding portion 213, the movement of the GPU assembly 30 is guided, that is, the GPU assembly 30 moves along the second direction Z. In this way, the accuracy of the mounting of the GPU assembly 30 can be improved, so as to ensure that the first plug-in portion 212 can be plugged into the second plug-in portion 3111, and the first connecting portion 211 can be connected to the second connecting portion 321.

Further, referring to FIG. 2, FIG. 8 and FIG. 11, the first guiding portion 213 is provided with a guiding slot 2131. The guiding slot 2131 extends along the second direction Z, and a notch of the guiding slot 2131 faces the first end 311 of the GPU video card 31. A top wall of the first guiding portion 213 along the second direction Z is provided with a first insertion opening 2132 in communication with the guiding slot 2131. The side of the second mounting portion 323 away from the first mounting portion 322 is provided in the guiding slot 2131 through the first insertion opening 2132. During the process of placing the GPU assembly 30 in the accommodating cavity 14, the side of the second mounting portion 323 away from the first mounting portion 322 enters the guiding slot 2131 through the first insertion opening 2132, and the second mounting portion 323 moves in the guiding slot 2131 along the second direction Z until the GPU assembly 30 is mounted in place.

In an embodiment, referring to FIG. 8, a plurality of first guiding portions 213 are provided, and the plurality of first guiding portions 213 are spaced apart along the first direction X. The plurality of first guiding portions 213 are in guiding cooperation with the plurality of first brackets 32 in a one-to-one correspondence. In this way, the movement of each GPU assembly 30 is guided, and the stability of the movement of each GPU assembly 30 in the second direction Z is ensured.

In one embodiment, referring to FIGS. 11 and 13, the first mounting portion 322 is provided with a through hole 3221. The first end 311 of the GPU video card 31 is provided with a fixing hole 3112 aligned with the through hole 3221. A first fixing member 34 is provided in the fixing hole 3112 and the through hole 3221. The first fixing member 34 may be a screw, a bolt, etc. During mounting, the first fixing member 34 is provided in the fixing hole 3112 and the through hole 3221, so that the first bracket 32 is detachably mounted to the first end 311 of the GPU video card 31 through the first fixing member 34. Therefore, the first bracket 32 can be removed from the GPU video card 31 to facilitate replacement of the first bracket 32.

In an embodiment, referring to FIG. 11, two fixing holes 3112 are provided, which are a first fixing hole 31121 and a second fixing hole 31122. The first fixing hole 31121 and the second fixing hole 31122 are spaced apart along the second direction Z.

The GPU video card 31 has various types such as NVDIA, KUNLUN, L20, MI210, RTX4090, RTX4090-T, and 4090. The fixing holes 33 of the GPU video card of different models are arranged in different ways. In order to ensure that the first bracket 32 can be mounted to the GPU video card of different models, in this embodiment, referring to FIG. 13, at least four through holes 3221 are provided, which are a first through hole 32211, a second through hole 32212, a third through hole 32213, and a fourth through hole 32214. The first through hole 32211, the second through hole 32212, the third through hole 32213, and the fourth through hole 32214 are spaced apart along the second direction Z. The first through hole 32211 is a circular hole. The second through hole 32212 is a first elliptical hole, and a long axis of the first elliptical hole extends along the second direction Z. The third through hole 32213 is a second elliptical hole, and A long axis of the second elliptical hole is inclined with respect to the second direction Z. The fourth through hole 32214 is a third elliptical hole, and a long axis of the third elliptical hole extends along the first direction X.

It should be noted that the first through hole 32211 is the circular hole, and the first through hole 32211 is used for positioning and error redundancy. The second through hole 32212 is the first elliptical hole, the long axis of the first elliptical hole extends along the second direction, and the second through hole 32212 is used for error redundancy. The third through hole 32213 is the second elliptical hole, the long axis of the second elliptical hole is inclined with respect to the second direction, and the third through hole 32213 is used for positioning. The fourth through hole 32214 is the third elliptical hole, the long axis of the third elliptical hole extends along the first direction, and the fourth through hole 32214 is used for positioning.

When the GPU video card 31 is a 4090 video card, one first fixing member 34 is provided in the first fixing hole 31121 and the third through hole 32213, and another first fixing member 34 is provided in the second fixing hole 31122 and the fourth through hole 32214.

When the GPU video card 31 is a NVDIA/KL/L200 video card, one first fixing member 34 is provided in the first fixing hole 31121 and the second through hole 32212, and another first fixing member 34 is provided in the second fixing hole 31122 and the fourth through hole 32214.

When the GPU video card 31 is a MI210GPU video card, one first fixing member 34 is provided in the first fixing hole 31121 and the third through hole 32213, and another first fixing member 34 is provided in the second fixing hole 31122 and the fourth through hole 32214.

When the GPU video card 31 is a RTX4090/RTX 4090-T video card, one first fixing member 34 is provided in the first fixing hole 31121 and the first through hole 32211, and another first fixing member 34 is provided in the second fixing hole 31122 and the fourth through hole 32214.

In an embodiment, referring to FIG. 2 and FIG. 8, the cross-beam body 21 is provided with a first ventilation hole 218 in communication with the accommodating cavity 14. During mounting, a fan is provided a side of the cross-beam assembly 20 away from the GPU assembly 30. When the fan is started, the fan blows cooling airflow into the accommodating cavity 14 through the first ventilation hole 218 to cool the GPU assembly 30 and prevent the temperature of the GPU assembly 30 from being too high.

Optionally, referring to FIG. 8, a plurality of first ventilation holes 218 are provided, and the plurality of first ventilation holes 218 are spaced apart in the first direction X. In this way, it can be ensured that the cooling airflow enters the accommodation cavity 14 through the first ventilation hole 218 to dissipate the heat from the GPU assembly 30, and the structural strength of the cross-beam body 21 is also ensured.

In an embodiment, referring to FIGS. 1 and 2, the computer case 10 includes a housing 11 and a cover 12. A top portion of the housing 11 in the second direction Z is provide with a first opening 111, and the cover 12 is provided at the first opening 111. During mounting, the cover 12 is opened, and the GPU assembly 30 is placed into the accommodating cavity 14 through the first opening 111. After the mounting is completed, the cover 12 is provided in the first opening 111.

Optionally, referring to FIG. 1 and FIG. 2, the cover 12 is movably provided in the first opening 111, and the cover 12 is capable of moving the housing 11 along a third direction Y. The third direction Y is perpendicular to the first direction X.

In an embodiment, referring to FIG. 1, the cover 12 is provided with a mounting opening. The computer case 10 further includes a latch assembly 15 provided at a mounting opening and connected to the cover 12. The latch assembly 15 is provided with a locking hole. In an embodiment, the locking hole is a strip-shaped hole, and the strip-shaped hole extends along the third direction Y.

Further, referring to FIG. 8, the cross-beam body 21 further includes a guiding member 23. In an embodiment, the guiding member 23 is a pin. The guiding member 23 extends in the second direction Z, and an end of the guiding member 23 away from the cross-beam body 21 is provided in the locking hole. In use, the cover 12 is moved in the third direction Y on the housing 11 until the guiding member 23 is located in the locking hole of the latch assembly 15, so as to secure the cover 12 to the housing 11.

In an embodiment, referring to FIG. 2 and FIG. 9, the cross-beam body 21 is provided with a first protrusion 214 provided on a side thereof away from the GPU assembly 30, and the first protrusion 214 extends in a direction away from the GPU assembly 30. In an embodiment, the first protrusion 214 is provided on the top portion of the cross-beam body 21 in the second direction Z. The guiding member 23 is connected to the first protrusion 214. In this way, the guiding member 23 is provided on the side of the cross-beam body 21 away from the GPU assembly 30, so as to prevent the latch assembly 15 from interfering with the GPU video card 31.

In an embodiment, referring to FIGS. 8 and 9, the cross-beam assembly 20 further includes a first support frame 24. The first support frame 24 is provided on a side of the first protrusion 214 facing the cover 12. The guiding member 23 is provided in the first support frame 24. Optionally, the first support frame is provided with a first through hole 241 adapted to a cross-sectional size of the guiding member 23. One end of the guiding member 23 away from the first protrusion 214 is provided in the first through hole 241, and the guiding member 23 is attached to a wall of the first through hole 241. In this way, the first support frame 24 supports the guiding member 23 to prevent the guiding member 23 from being damaged due to the pressure of the cover 12.

Referring to FIG. 8 and FIG. 9, a bottom portion of the cross-beam body 21 along the second direction Z is provided with a second protrusion 215, and the second protrusion 215 is opposite to the first protrusion 214. The cross-beam assembly 20 further includes a second support frame 25 provided between the first protrusion 214 and the second protrusion 215. The second support frame 25 is configured to support the first protrusion 214. In this way, the second support frame 25 can reinforce the first protruding portion 214 to ensure the stability of the guiding member 23.

Further, referring to FIG. 9, the second support frame 25is provided with a second ventilation hole 251 in communication with the first ventilation hole 218. Since the second support frame 25 is provided with the second ventilation hole 251, the first ventilation hole 218 can be prevented from being blocked by the second support frame 25, thereby ensuring the heat dissipation effect.

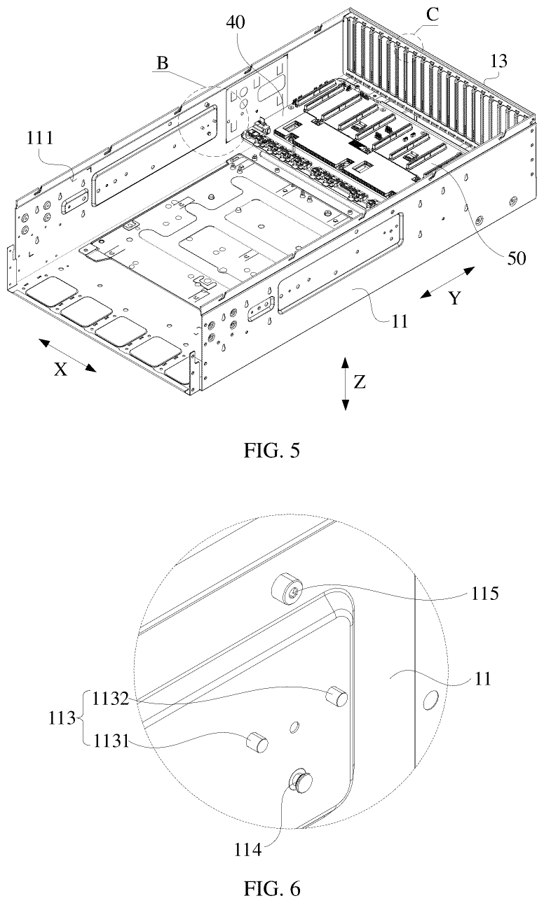

In an embodiment, referring to FIG. 5 and FIG. 6, two opposite side walls of the computer case 10 are each provided with a second guiding portion 113. The second guiding portion 113 is in guiding cooperation with an end portion of the cross-beam body 21 along the first direction X, so as to enable the cross-beam body 21 to move in the second direction Z. In this way, the movement of the cross-beam body 21 in the second direction Z is guided, and the stability of the movement of the cross-beam body 21 in the second direction Z is ensured.

Optionally, referring to FIG. 5 and FIG. 6, the second guiding portion 113 includes a first guiding body 1131 and a second guiding body 1132. In an embodiment, the first guiding body 1131 and the second guiding body 1132 are pins. The first guiding body 1131 and the second guiding body 1132 are spaced apart from each other along the third direction Y. The end portion of the cross-beam body 21 is located between the first guiding body 1131 and the second guiding body 1132. During mounting, when the GPU assembly 30 is placed in the accommodating cavity 14, the end portion of the cross-beam body 21 in the first direction X is located between the first guiding body 1131 and the second guiding body 1132, and the first guiding body 1131 and the second guiding body 1132 cooperate to guide the movement of the cross-beam body 21, so that the cross-beam body 21 moves along the second direction, thereby ensuring the accuracy of the mounting of the cross-beam body 21.

In an embodiment, referring to FIG. 8 and FIG. 9, both ends of the cross-beam body 21 along the first direction X are each provided with a limiting groove 216. The limiting groove 216 extends along the second direction Z. A bottom wall of the limiting groove 216 along the second direction Z is provided with a second insertion opening 2161 in communication with the limiting groove 216.

Further, referring to FIG. 5 and FIG. 6, two opposite side walls of the housing 11 are each provided with a limiting member 114. In an embodiment, the limiting member 114 is an I-shaped nail. The limiting member 114 is provided in the limiting groove 216 through the second insertion opening 2161. During the process of placing the GPU assembly 30 in the accommodating cavity 14 along the second direction Z, the limiting member 114 enters the limiting groove 216 through the second insertion opening 2161. When the limiting member 114 abuts against a top wall of the limiting groove 216 in the second direction X, the limiting member 114 limits the GPU assembly 30 to continue to move, so that the GPU assembly 30 is mounted in place.

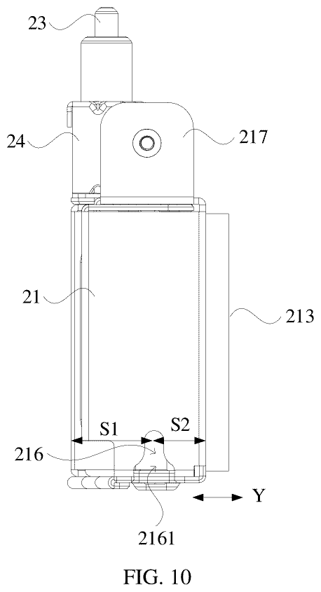

In an embodiment, referring to FIGS. 8 and 10, a distance S1 between the center of the limiting groove 216 in the third direction Y and one side of the end portion of the cross-beam body 21 in the first direction X is different from a distance S2 between the center of the limiting groove 216 in the third direction Y and the other side of the end portion of the cross-beam body 21 in the first direction X. In this way, mounting errors can be avoided.

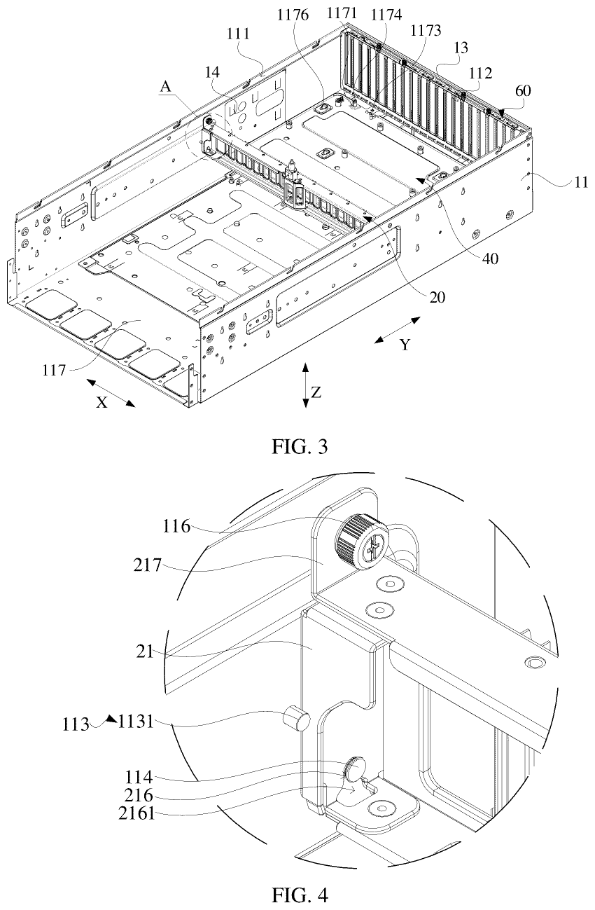

In an embodiment, referring to FIG. 3, FIG. 4 and FIG. 8, both ends of the cross-beam body 21 in the first direction X are provided with connecting lugs 217. In an embodiment, the connecting lugs 217 are provided at the top portion of the cross-beam body 21 in the second direction Z. Each connecting lug 217 is provided with a third connecting hole 2171.

Further, referring to FIG. 4, FIG. 5 and FIG. 6, two opposite side walls of the computer case 10 are each provided with a fourth connecting hole 115 in communication with corresponding third connecting hole 2171. A second connecting member 116 is provided in the third connecting hole 2171 and the fourth connecting hole 115. In an embodiment, the second connector 116 is a screw. In this way, the cross-beam assembly 20 can be detachably mounted to the computer case 10 through the second connecting member 116, so that the cross-beam assembly 20 can be removed from the computer case 10 to facilitate replacement and maintenance of the cross-beam assembly 20.

In an embodiment, referring to FIG. 2, FIG. 3 and FIG. 5, the electronic device further includes a tray 40 and a GPU card 50 that are accommodated in the accommodating cavity 14. The tray 40 is located below the GPU video card 31 along the second direction, and the tray 40 is connected to the computer case 10. The GPU card 50 is connected to a side of the tray 40 facing the GPU video card 31, and the GPU card 50 is electrically connected to the GPU video card 31. Thus, the tray 40 supports the GPU card 50 to facilitate the mounting of the GPU card 50.

It should be noted that, in this embodiment, the GPU card 50 has two types, one is a switch card, and the other is a HBA (Host Bus Adapter) card.

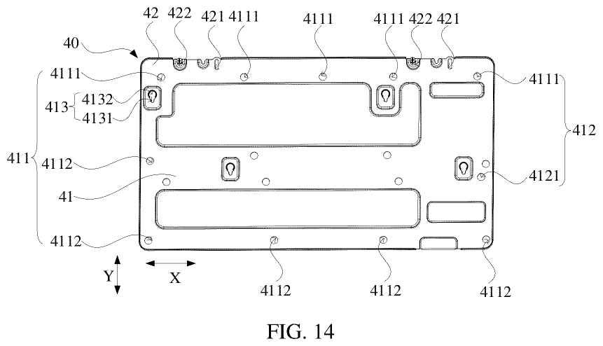

In order to be compatible with the mounting of the switch card and the HBA card, referring to FIG. 14, the tray 40 is provided with a first area 41. The first area 41 is provided with a first group of holes 411 and a second group of holes 412. The first group of holes 411 is configured to mount a switch card, and the second group of holes 412 is configured to mount a HBA card. In this way, both the switch card and the HBA card are provided on the same tray 40, which is beneficial to saving the cost.

Further, referring to FIG. 14, the first area 41 is provided with a plurality of common holes 4111, a plurality of first mounting holes 4112, and a plurality of second mounting holes 4121. The plurality of common holes 4111 and the plurality of first mounting holes 4112 form the first group of holes 411. The first group of holes 411 are configured to be in communication with hole positions of the switch card in a one-to-one correspondence. The plurality of common holes 4111 and the plurality of second mounting holes 4121 form the second group of holes 412. The second group of holes 412 are configured to be in communication with hole positions of the HBA card in a one-to-one correspondence.

It should be understood that the number, position and arrangement of the common holes 4111, the first mounting holes 4112 and the second mounting holes 4121 are set according to the hole positions of the switch card and the HBA card, so as to ensure that the common holes 4111 and the first mounting holes 4112 are in communication with the hole positions of the switch card in a one-to-one correspondence, and the common holes 4111 and the second mounting holes 4121 are in communication with the hole positions of the HBA card in a one-to-one correspondence, so that the tray 40 is compatible with the mounting of the switch card and the HBA card.

In an embodiment, referring to FIG. 14, in the third direction Y, one row of common holes 4111 is provided, two rows of first mounting holes 4112 are provided, and one row of common holes 4111 and two rows of first mounting holes 4112 are each spaced apart along the third direction Y. In the row of common holes 4111, a plurality of common holes 4111 are provided, and the plurality of common holes 4111 are spaced apart in the first direction X. In an embodiment, five common holes 4111 are provided, and the five common holes 4111 are spaced apart along the first direction X. In each row of first mounting holes 4112, a plurality of first mounting holes 4112 are provided, and the plurality of first mounting holes 4112 are spaced apart along the first direction X. In an embodiment, in each row of the first mounting holes 4112, four first mounting holes 4112 are provided, and the four first mounting holes 4112 are spaced apart along the first direction X.

In an embodiment, referring to FIG. 14, in the third direction Y, one row of the second mounting holes 4121 is provided, and the row of common holes 4111 is spaced from the row of second mounting holes 4121 along the third direction Y. In each row of the second mounting holes 4121, a plurality of second mounting holes 4121 are provided, and the plurality of second mounting holes 4121 are spaced apart along the first direction X. In an embodiment, four second mounting holes 4121 are provided in each row of the second mounting holes 4121, and the four second mounting holes 4121 are spaced apart along the first direction X. The row of second mounting holes 4121 is located between the two rows of first mounting holes 4112. It should be understood that an area where the common holes 4111 and the first mounting holes 4112 are located is greater than an area where the common holes 4111 and the second mounting holes 4121 are located.

In an embodiment, referring to FIG. 14, the tray 40 is provided with a first gourd hole 413. Specifically, the first gourd hole 413 includes a first hole 4131 and a second hole 4132, a diameter of the first hole 4131 is less than a diameter of the second hole 4132. The first hole 4131 and the second hole 4132 are arranged along the third direction Y. The first hole 4131 is in communication with the second hole 4132.

Further, referring to FIG. 3, the housing 11 has a bottom wall 117 opposite to the cover 12. The bottom wall 117 is provided with a second fixing member 1176, and the second fixing member 1176 is movably provided in the first gourd hole 413. In an embodiment, the bottom wall 117 is provided with a first via hole 1175, and the second fixing member 1176 is provided in the first via hole 1175. The second fixing member 1176 may be an I-shaped nail.

The second fixing member 1176 is a capable of moving in the first gourd hole 413 along the third direction Y, so that the tray 40 has a locked state and an unlocked state. When the tray is in the locked state, the second fixing member 1176 is provided in the first hole 4131. When the tray is in the unlocked state, the second fixing member 1176 is provided in the second hole 4132.

During mounting, the tray 40 is placed on the bottom wall 117 of the housing 11, and the tray 40 is pushed along the third direction Y, so that the first hole 4131 is in communication with the first via hole 1175, and then the second fixing member 1176 is provided in the first hole 4131 and the first via hole 1175. In this way, the tray 40 is locked to the bottom wall 117 of the housing 11 by the second fixing member 1176.

During disassembly, the tray 40 is pushed in the third direction Y, so that the second hole 4132 is in communication with the first via hole 1175, and then the second fixing member 1176 is rotated to remove the tray 40 from the computer case 10.

After the GPU card 50 is mounted in the tray 40, the tray 40 can be mounted in the computer case 10. Since the first area 41 of the tray 40 is covered with the GPU card 50 after the tray 40 is mounted with the GPU card 50, an operator cannot see the second fixing member 1176 located in the first area 41. In an embodiment, referring to FIG. 14, an edge of the tray 40 and the first area 41 enclose a second area 42. The second area 42 is provided with a first fastening hole 422 and a second positioning hole 421. In an embodiment, the second positioning hole 421 is a strip-shaped hole, and the strip-shaped hole extends along the third direction Y.

For better positioning, at least two second positioning holes 421 are provided. In order to improve the firmness of the assembly, at least two first fixing members 1174 are provided. For ease of operation, the second positioning holes 421 and the first fastening members 1174 are provided on a side of the tray 40 away from the cross-beam assembly 20.

Further, referring to FIG. 3, the bottom wall 117 of the housing 11 is further provided with a second fastening hole 1171 and a second via hole 1172. The first fastening member 1174 is provided in the first fastening hole 422 and the second fastening hole 1171. A positioning member 1173 is provided in the second positioning hole 421 and the second via hole 1172. In an embodiment, the first fastening member 1174 is a spring screw, and the positioning member 1173 is a positioning pin. During mounting, the tray 40 is placed on the bottom wall 117 of the housing 11, and the positioning member 1173 is provided in the second positioning hole 421 and the second via hole 1172. Then, the tray 40 is pushed along the third direction Y, so that the first hole 4131 is in communication with the first via hole 1175 and the first fastening hole 422 is in communication with the second fastening hole 1171. Then, the second fixing member 1176 is provided in the first hole 4131 and the first via hole 1175. Finally, a first fastening member 1174 is provided in the first fastening hole 422 and the second fastening hole 1171.

In an embodiment, referring to FIG. 3, an end of the housing 11 in the third direction Y is provided with a second opening 112 in communication with the accommodating cavity 14. It should be understood that the second opening 112 is located on a side of the GPU card 31 away from the first end 311.

Further, referring to FIG. 3, the computer case 10 further includes a rear window 13 13 provided in the second opening 112. In this way, by providing the rear window 13, the heat generated by the GPU assembly 30 can be exchanged with the air outside the computer case 10 through the rear window 13, thereby reducing the temperature of the GPU assembly 30.

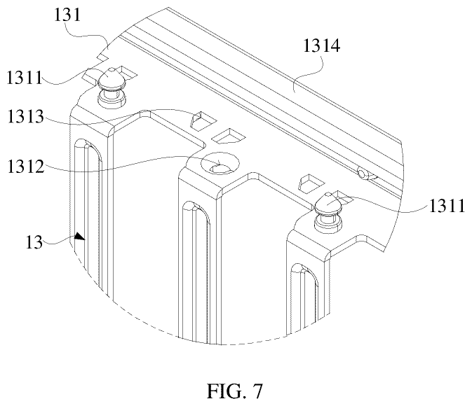

Specifically, referring to FIG. 6 and FIG. 7, the rear window 13 is provided with a flange 131 extending in a direction away from the GPU assembly 30.

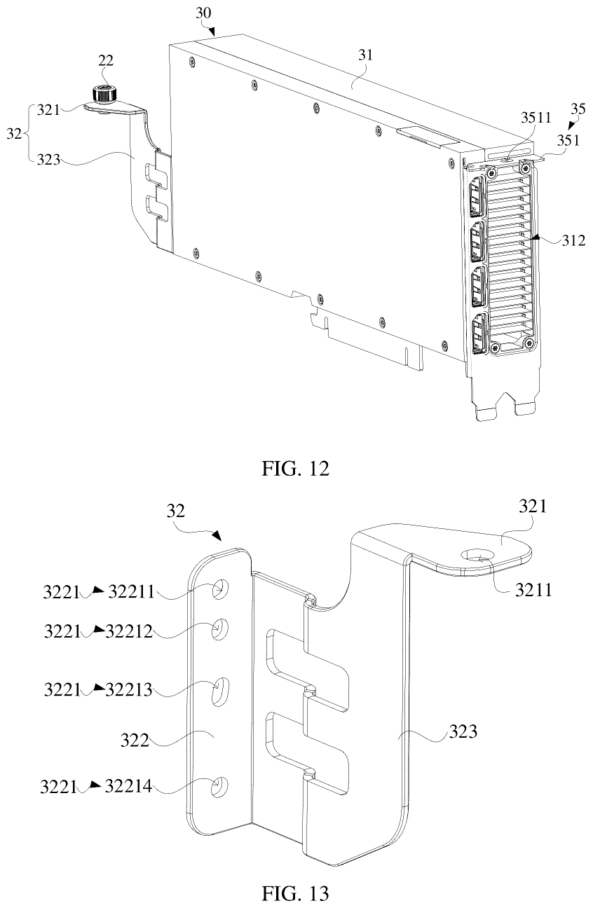

In an embodiment, referring to FIG. 11 and FIG. 12, the GPU video card 31 further has a second end 312 opposite to the first end 311. It should be understood that the second end 312 refers to the side of the GPU video card 31 away from the first end 311. Further, the second end 312 of the GPU video card 31 is provided with a second bracket 35. The second bracket 35 includes a third connecting portion 351 connected to the flange 131 of the rear window 13.

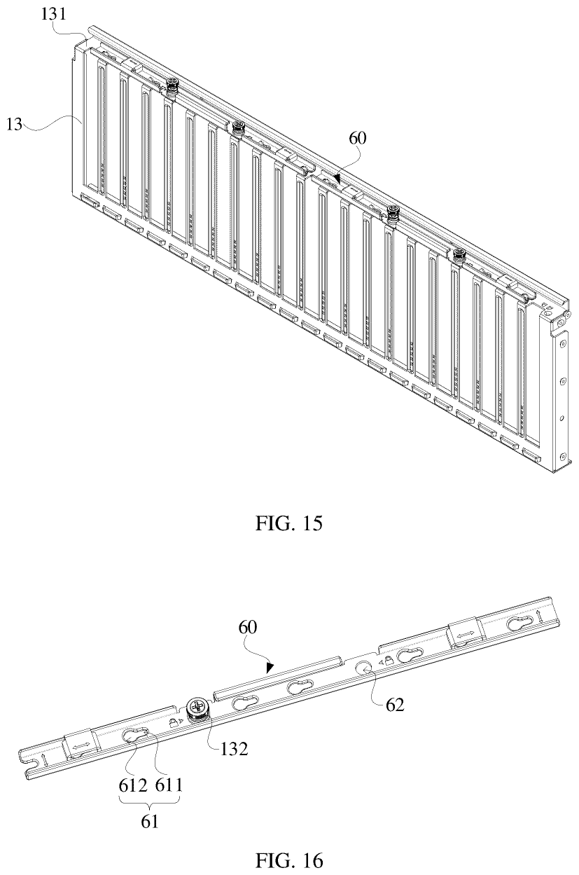

Further, referring to FIGS. 15 and 16, the electronic device further includes a pressing member 60. The pressing member 60 is provided on the flange 131, and the pressing member 60 is configured to press the third connecting portion 351 against the flange 131 of the rear window 13.

In an embodiment, referring to FIGS. 16 and 18, the pressing member 60 is provided with a second gourd hole 61. The second gourd hole 61 includes a third hole 611 and a fourth hole 612. A diameter of the third hole 611 is less than a diameter of the fourth hole 612. The third hole 611 and the fourth hole 612 are arranged along the first direction X, and the third hole 611 is in communication with the fourth hole 612.

Further, referring to FIG. 7, the flange 131 of the rear window 13 is provided with a third fixing member 1311. In an embodiment, the third fixing member 1311 is an I-shaped nail. Referring to FIG. 12, in order to improve the firmness of the third connecting portion 351, at least a portion of the third connecting portion 351 is provided with a fifth connecting hole 3511, and the third fixing member 1311 is provided in the fifth connecting hole 3511.

The pressing member 60 can be moved in the first direction X on the flange 131 of the rear window 13, so that the pressing member 60 has a locked state and an unlocked state. In the locked state, the third fixing member 1311 is provided in the third hole 611. In the unlocked state, the third fixing member 1311 is provided in the fourth hole 612.

In an embodiment, referring to FIGS. 7 and 16, the pressing member 60 is further provided with a third fastening hole 62. The flange 131 of the rear window 13 further provided with a fourth fastening hole 1312. A second fastening member 132 is provided in the third fastening hole 62 and the fourth fastening hole 1312. In an embodiment, the second fastening member 132 is a spring screw. In order to improve the firmness of the third connecting portion 351, at least a portion of the third connecting portion 351 is further provided with a fifth fastening hole, and the second fastening member 132 is further provided in the fifth fastening hole.

After the GPU assembly 30 is mounted, the third connecting portion 351 of the second bracket 35 is overlapped on the flange 131 of the rear window 13, the third fixing member 1311 extends through the fourth hole 612, and then the pressing member 60 is pushed along the first direction X, so that the third fixing member 1311 moves from the fourth hole 612 to the third hole 611, the third fastening hole 62 is in communication with the fourth fastening hole 1312, and finally the second fastening member 132 is provided in the third fastening hole 62 and the fourth fastening hole 1312. In this way, the second bracket 35 is fixed to the rear window 13 by the pressing member 60, which simplifies the mounting and improves the mounting efficiency.

During disassembly, the second fastening member 132 is first loosened, and then the pressing member 60 is pushed reversely in the first direction X, so that the third fixing member 1311 moves from the third hole 611 to the fourth hole 612. In this way, the pressing member 60 can be removed from the rear window 13, which facilitates disassembly and improves disassembly efficiency.

In order to improve the firmness of mounting the second bracket 35 to the rear window 13, a plurality of second gourd holes 61 and a plurality of third fastening holes 62 are provided, and the plurality of second gourd holes 61 and the plurality of third fastening holes 62 are spaced apart along the first direction X. Meanwhile, a plurality of third fixing members 1311 and a plurality of fourth fastening holes 1312 are provided, and the plurality of third fixing members 1311 and the plurality of fourth fastening holes 1312 are spaced apart along the first direction X.

In another embodiment, referring to FIG. 7, a support portion 1314 is provided on a side of the flange 131 away from the GPU assembly 30.

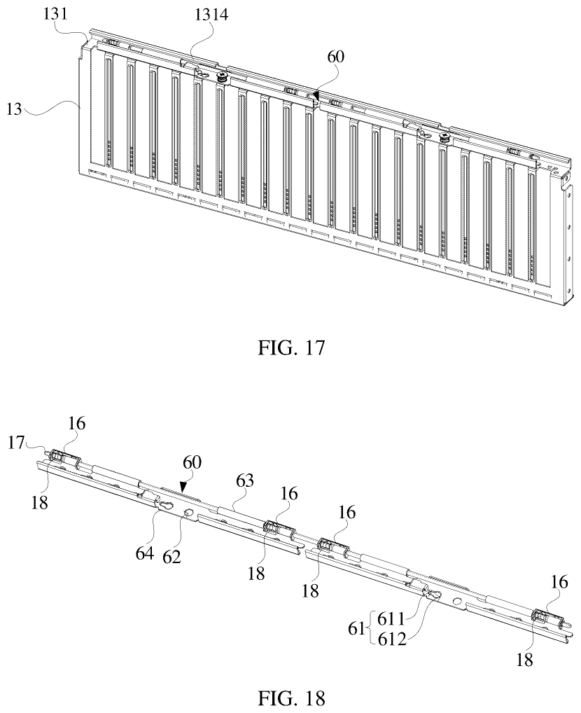

Further, referring to FIGS. 17, 18, and 19, the pressing member 60 has a first side 63 and a second side 64. The first side 63 is rotatably connected to the rear window 13. The pressing member 60 is capable of rotating away from the GPU assembly 30 until the second side 64 overlaps the support portion 1314. Thus, the support portion 1314 supports the pressing member 60.

In an embodiment, referring to FIGS. 17, 18, and 19, the computer case 10 further includes a mounting base 16 and a connecting shaft 17. The mounting base 16 is provided in the rear window 13 and is provided with a second through hole 161. The connecting shaft 17 extends in the first direction X. The connecting shaft 17 is provided in the second through hole 161. The first side 63 of the pressing member 60 is rotatably and movably connected to the connecting shaft 17. It should be understood that the pressing member 60 can be rotated about an axial direction of connection shaft 17 while the pressing member 60 can be moved along the axial direction of the connecting shaft 17.

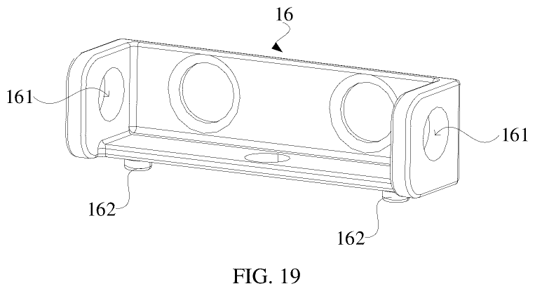

Further, referring to FIG. 7 and FIG. 19, the mounting base 16 is provided with a first positioning portion 162, the flange 131 is provided with a second positioning portion 1313, and the first positioning portion 162 is engaged with the second positioning portion 1313. During mounting, the first positioning portion 162 is engaged with the second positioning portion 1313, and then the mounting base 16 is fixed to the rear window 13. In this way, by providing the first positioning portion 162 and the second positioning portion 1313, the mounting accuracy of the mounting base 16 and the mounting efficiency can be improved.

Optionally, the first positioning portion 162 is provided with a positioning column, the second positioning portion 1313 is provided with a positioning hole, and the positioning column is provided in the positioning hole. Alternatively, the first positioning portion 162 is provided with a positioning hole, and the second positioning portion 1313 is provided with a positioning column.

In an embodiment, referring to FIG. 18, the computer case 10 further includes an elastic member 18 capable of telescoping in the first direction X. In an embodiment, the elastic member 18 is a spring, and the spring is sleeved on the connecting shaft 17. One end of the elastic member 18 in the first direction X is connected to the mounting base 16, and the other end of the elastic member 18 in the first direction X is connected to the pressing member 60.

After the GPU assembly 30 is mounted, the third connecting portion 351 of the second bracket 35 is overlapped on the flange 131 of the rear window 13, the third fixing member 1311 extends through the fourth hole 612, and then the pressing member 60 is pushed along the first direction X, so that the third fixing member 1311 moves from the fourth hole 612 to the third hole 611, and the third fastening hole 62 is in communication with the fourth fastening hole 1312. Finally, the second fastening member 132 is provided in the third fastening hole 62 and the fourth fastening hole 1312.

During disassembling, the second fastening member 132 is first loosened, and then the pressing member 60 is pushed reversely in the first direction X, so that the third fixing member 1311 is withdrawn from the third hole 611 to the fourth hole 612. The pressing member 60 is then rotated about the axial direction of the connecting shaft 17 in a direction away from the GPU assembly 30 until the second side 64 of the pressing member 60 overlaps the support portion 1314. During the process of reversely pushing the pressing member 60 in the first direction X, the elastic member 18 is gradually compressed. Under the action of the elastic member 18, the pressing member 60 will not rotate reversely and falls down.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure, but are not intended to limit the protection scope of the present disclosure. Any variation or replacement readily figured out by a person skilled in the art within the technical scope disclosed in the present disclosure shall all fall within the protection scope of the present disclosure.

What is claimed is:

1. An electronic device, comprising:
a computer case;
a cross-beam assembly provided in the computer case, wherein the cross-beam assembly comprises a cross-beam body, two ends of the cross-beam body along a first direction are connected to two opposite side walls of the computer case, respectively, t he cross-beam body and the computer case cooperatively enclose an accommodating cavity, the cross-beam body comprises a first connecting portion and a first plug-in portion that are staggered in the first direction; and
a GPU assembly provided in the accommodating cavity, wherein the GPU assembly comprises a GPU video card and a first bracket, the GPU video card has a first end facing the cross-beam assembly, the first end comprises a second plug-in portion, the first bracket is provided at the first end and comprises a second connecting portion, the second plug-in portion and the second connecting portion are staggered in the first direction, the first plug-in portion is plugged into the second plug-in portion, and the first connecting portion is connected to the second connecting portion.

2. The electronic device according to claim 1, wherein the first bracket further comprises a first mounting portion and a second mounting portion, the first mounting portion is spaced apart from the second plug-in portion along a second direction, the second direction is perpendicular to the first direction, the second mounting portion is provided on a side of the first mounting portion, the second mounting portion extends from the first mounting portion toward the cross-beam assembly, the second connecting portion is provided on a side of the second mounting portion away from the first mounting portion, so that the first mounting portion and the second connecting portion are staggered in the first direction.

3. The electronic device according to claim 2, wherein the second connecting portion extends from the second mounting portion toward the cross-beam assembly, so that the second connecting portion is connected to the first connecting portion.

4. The electronic device according to claim 2, wherein the cross-beam body further comprises a first guiding portion facing the first end, the first guiding portion is in guiding cooperation with a side of the second mounting portion away from the first mounting portion, and the first guiding portion is configured to guide a movement of the first bracket along the second direction.

5. The electronic device according to claim 4, wherein the first guiding portion is provided with a guiding slot extending along the second direction, a notch of the guiding slot faces the first end, a top wall of the first guiding portion along the second direction is provided with a first insertion opening in communication with the guiding slot, and the side of the second mounting portion away from the first mounting portion is provided in the guiding slot through the first insertion opening.

6. The electronic device according to claim 1, wherein the first connecting portion and the first plug-in portion are provided on a top portion of the cross-beam body along a second direction, the top portion of the cross-beam body is lower than a bottom portion of the second plug-in portion in the second direction, and the first direction is perpendicular to the second direction.

7. The electronic device according to claim 1, wherein the cross-beam body is provided with a first ventilation hole in communication with the accommodating cavity.

8. The electronic device according to claim 1, wherein the computer case comprises a housing and a cover, a top portion of the housing in a second direction is provided with a first opening, the cover is provided in the first opening, the cover is capable of moving on the housing along a third direction, the cover is provided with a latch assembly, the latch assembly is provided with a locking hole, the first direction, the second direction, the third direction are perpendicular to each other, the cross-beam assembly further comprises a guiding member, the guiding member is provided on the cross-beam body along the second direction, and an end of the guiding member away from the cross-beam body is provided in the locking hole.

9. The electronic device according to claim 8, wherein the cross-beam body is provided with a first protrusion provided on a side thereof away from the GPU assembly, the first protrusion extends in a direction away from the GPU assembly, and the guiding member is connected to the first protrusion.

10. The electronic device according to claim 9, wherein the cross-beam assembly further comprises a first support frame, the first support frame is provided on a side of the first protrusion facing the cover, the first support frame is connected to the guiding member, and the first support frame is configured to support the guiding member.

11. The electronic device according to claim 9, wherein a bottom portion of the cross-beam body along the second direction is provided with a second protrusion, and the second protrusion is opposite to the first protrusion, the cross-beam assembly further comprises a second support frame provided between the first protrusion and the second protrusion, and the second support frame is configured to support the first protrusion.

12. The electronic device according to claim 1, wherein two opposite side walls of the computer case are each provided with a second guiding portion, the second guiding portion is in guiding cooperation with an end of the cross-beam body along the first direction, and the second guiding portion is configured to guide a movement of the cross-beam body along a second direction.

13. The electronic device according to claim 1, wherein both ends of the cross-beam body along the first direction are each provided with a limiting groove, the limiting groove extends along a second direction, a bottom wall of the limiting groove along the second direction is provided with a second insertion opening in communication with the limiting groove, two opposite side walls of the computer case are each provided with a limiting member, and the limiting member is provided in the limiting groove through the second insertion opening.

14. The electronic device according to claim 1, wherein the first plug-in portion is provided with a first power connector, the second plug-in portion is provided with a second power connector, and the first power connector is electrically connected to the second power connector.

15. The electronic device according to claim 1, wherein a plurality of first plug-in portions and a plurality of first connecting portions are provided, the plurality of first plug-in portions and the plurality of first connecting portions are alternately arranged along the first direction, a plurality of GPU assemblies are provided, the plurality of GPU assemblies are arranged along the first direction, a plurality of second plug-in portions and a plurality of second connecting portions are alternately arranged along the first direction, the plurality of first plug-in portions are plugged into the plurality of second plug-in portions in a one-to-one correspondence, and the plurality of first connecting portions are connected to the plurality of second connecting portions in a one-to-one correspondence.

16. The electronic device according to claim 1, further comprising a tray and a GPU card that are accommodated in the accommodating cavity, wherein the tray is located below the GPU video card along a second direction, the GPU card is connected to a side of the tray facing the GPU video card, and the GPU card is electrically connected to the GPU video card.

17. The electronic device according to claim 16, wherein the tray is provided with a first area, the first area is provided with a first group of holes and a second group of holes, the first group of holes are configured to mount a switch card, and the second group of holes are configured to mount a HBA (Host Bus Adapter) card.

18. The electronic device according to claim 17, wherein the first area is provided with a plurality of common holes, a plurality of first mounting holes, and a plurality of second mounting holes, the plurality of common holes and the plurality of first mounting holes form the first group of holes, the first group of holes are configured to be in communication with hole positions of the switch card in a one-to-one correspondence, the plurality of common holes and the plurality of second mounting holes form the second group of holes, and the second group of holes are configured to be in communication with hole positions of the HBA card in a one-to-one correspondence.

19. The electronic device according to claim 16, wherein the tray is provided with a first gourd hole, the first gourd hole comprises a first hole and a second hole, a diameter of the first hole is less than a diameter of the second hole, the first hole and the second hole are arranged along a third direction, the first hole is in communication with the second hole, the computer case has a bottom wall, the bottom wall is provided with a fixing member provided in the first gourd hole, the fixing member is capable of moving in the first gourd hole along the third direction, so that the tray has a locked state and an unlocked state, the fixing member is provided in the first hole when the tray is in the locked state, and the fixing member is provided in the second hole when the tray is in the unlocked state.

20. The electronic device according to claim 17, wherein an edge of the tray and the first area enclose a second area, the second area is provided with a first fastening hole and a positioning hole, the positioning hole extends along a third direction, a bottom wall of the computer case is further provided with a second fastening hole and a via hole, a first fastening member is provided in the first fastening hole and the second fastening hole, and a positioning member is provided in the positioning hole and the via hole.
